(19) United States
(12) Patent Application Publication
(10) Pub. No.: US 2024/0077543 A1
(43) Pub. Date: Mar. 7, 2024

(54) Battery Pack and Current Monitoring Method Thereof

(71) Applicant: RICHTEK TECHNOLOGY CORP., Hsinchu County (TW)

(72) Inventors: Hsu-Kai Hou, Hsinchu City (TW); Po-Ching Lee, Hsinchu County (TW); Tseng-Chuan Wu, Hsinchu County (TW)

(73) Assignee: RICHTEK TECHNOLOGY CORP., Hsinchu County (TW)

(21) Appl. No.: 18/132,427

(22) Filed: Apr. 10, 2023

Related U.S. Application Data
(60) Provisional application No. 63/403,302, filed on Sep. 2, 2022.

(30) Foreign Application Priority Data
Dec. 21, 2022 (TW) 111149089

(51) Int. Cl. G01R 31/3842; H01M 50/204

(52) U.S. Cl. CPC G01R 31/3842; H01M 50/204

(57) ABSTRACT

A battery pack includes a group of cells, a current path switch coupled to the group of cells, and a current monitoring system. The current monitoring system includes a signal detection unit, a logic unit and a current path control unit. The signal detection unit is coupled to the group of cells and/or a positive terminal of the battery pack, and used to detect at least one voltage signal of the group of cells and/or of the positive terminal of the battery pack. The logic unit is coupled to the signal detection unit, and used to generate a calculated value of a voltage signal of the at least one voltage signal and generate a logic signal according to the calculated value. The current path control unit is coupled to the logic unit and the current path switch, and used to control the current path switch according to the logic signal.

### CROSS REFERENCE TO RELATED APPLICATIONS

This application claims the benefit of U.S. Provisional Application No. 63/403,302, filed on Sep. 2, 2022. The content of the application is incorporated herein by reference.

### BACKGROUND OF THE INVENTION

### 1. Field of the Invention

The present invention is related to battery packs, and more particularly to battery packs and its current mentoring.

### 2. Description of the Prior Art

Rechargeable battery packs are widely used in the consumer electronics market, covering mobile phones, notebook computers, game consoles, digital cameras, portable devices, etc. A battery pack refers to a group of identical batteries or battery cells coupled together in series and/or in parallel. Components of battery packs also include interconnects for providing electrical conductivity.

The output power of the battery refers to the ability of the battery to output energy per unit time. Rated voltage is the maximum voltage that can be applied to an electrical device or system safely at a given ambient temperature or terminal temperature. It is determined by the design, construction, and materials of the device or system, and changing it may require significant modifications or affect its safety, performance, and reliability. The same definition applies to rated current. Rated current indicates the maximum amount of current that can be safely handled by the device or machine without causing damage or overheating. At a given rated voltage, the output power of the battery increases with increasing electrode surface area and operating temperature. At the same rated voltage the output power decreases with decreasing operating temperature.

A short circuit occurs when an electric current deviates from its intended path and flows through a low-resistance alternative route. It can be caused by various factors, such as damaged wires, loose connections, water intrusion, or human error. A short circuit can result in electric current intensity exceeding rated current, which may cause circuit damage, overheating, fire or explosion. Generally, rechargeable battery packs are provided with current sensing resistors. According to Ohm's law, when current flows through a resistor, a voltage difference is generated across the resistor. The current through the resistor can be obtained by dividing the voltage difference by the resistance of the resistor (I=V/R). If a current sensing resistor with large resistance is implemented to obtain a larger voltage difference, it can be prone to overheating. Therefore, it is desirable to implement a current sensing resistor with the smallest possible resistance. When short circuit occurs, that is, the amount of current exceeds the normal range (or the rated current), the protection mechanism of the circuit can detect the abnormal current by sensing the voltage at both terminals of the current sensing resistor. Then, it can cut off the current path and stop the circuit operation to ensure safety. However, when the current sensing resistor itself becomes faulty, it is impossible to monitor the voltage across the resistor to determine the current, causing the protection mechanism to fail.

### SUMMARY OF THE INVENTION

An embodiment provides a battery pack including a group of cells, a current path switch coupled to the group of cells, and a current monitoring system. The current monitoring system includes a signal detection unit, a logic unit and a current path control unit. The signal detection unit is coupled to the group of cells and/or a positive terminal of the battery pack, and used to detect at least one voltage signal of the group of cells and/or of the positive terminal of the battery pack. The logic unit is coupled to the signal detection unit, and used to generate a calculated value of a voltage signal of the at least one voltage signal and generate a logic signal according to the calculated value. The current path control unit is coupled to the logic unit and the current path switch, and used to control the current path switch according to the logic signal.

Another embodiment provides a current monitoring method for a battery pack. The battery pack includes a group of cells, a current path switch and a current monitoring system. The current monitoring system includes a signal detection unit, a logic unit and a current path control unit. The current path switch is coupled to the group of cells. The signal detection unit is coupled to the group of cells and/or a positive terminal of the battery pack. The logic unit is coupled to the signal detection unit. The current path control unit is coupled to the logic unit and the current path switch. The method includes detecting at least one voltage signal of the group of cells and/or of the positive terminal of the battery pack by the signal detection unit, generating a calculated value of a voltage signal of the at least one voltage signal, generating a logic signal according to the calculated value by the logic unit, and controlling the current path switch according to the logic signal by the current path control unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a battery pack of an embodiment of the present invention.

FIG. 2 is a diagram of charging the battery pack in FIG. 1 of an embodiment.

FIG. 3 is a timing diagram of charging the battery pack in FIG. 2.

FIG. 4 is a diagram of discharging the battery pack in FIG. 1 of an embodiment.

FIG. 5 is a timing diagram of discharging the battery pack in FIG. 4.

FIG. 6 is a diagram of discharging the battery pack in FIG. 1 of another embodiment.

FIG. 7 is a timing diagram of discharging the battery pack in FIG. 6.

FIG. 8 is a flowchart of the current monitoring method for the battery pack in FIG. 1.

### DETAILED DESCRIPTION

Certain terms are used throughout the description and following claims to refer to particular elements. As one skilled in the art will understand, electronic equipment manufacturers may refer to an element by different names. This disclosure does not intend to distinguish between elements that differ in name but not function. In the following description and in the claims, the terms “comprise”, “include” and “have” are used in an open-ended fashion, and thus should be interpreted to mean “include, but not limited to . . . ”. The term “substantially” as used herein are inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” means within one or more standard deviations. The term “same” may also refer to “about” because of the process deviation or fluctuation.

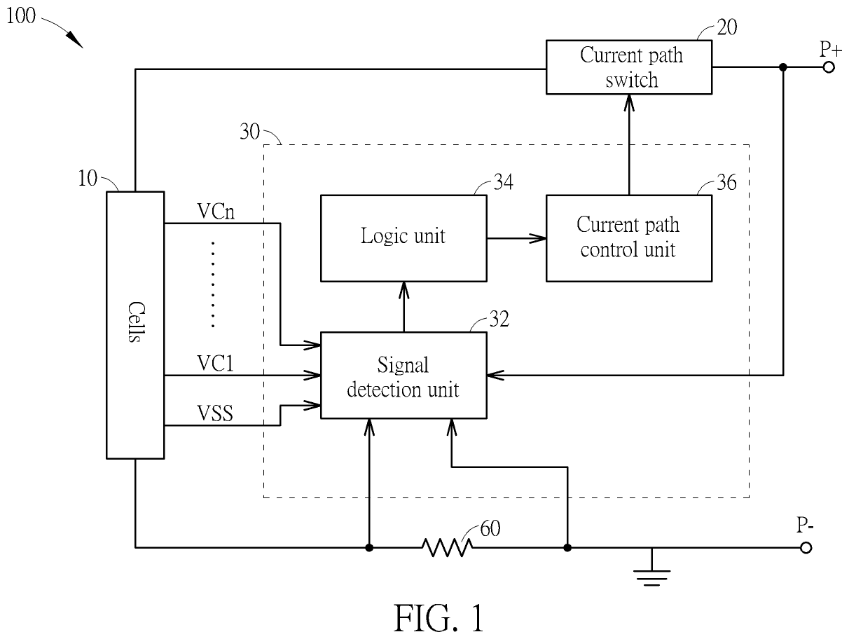

FIG. 1 is a diagram of a battery pack 100 of an embodiment of the present invention. The battery pack 100 includes a group of cells 10 (hereinafter referred to as the cells 10), a current path switch 20, a current monitoring system 30, and a current sensing resistor 60. The current monitoring system 30 includes a signal detection unit 32, a logic unit 34, and a current path control unit 36. The current path switch 20 is coupled to the cells 10. The signal detection unit 32 is coupled to the cells 10 and the positive terminal P+ of the battery pack 100, for detecting at least one voltage signal of the cells 10 and/or the positive terminal P+ of the battery pack 100. That is, the signal detection unit 32 can detect the voltage signal of the cells 10, and it can also detect the voltage signal of the positive terminal P+ of the battery pack 100. The logic unit 34 is coupled to the signal detection unit 32, for generating a calculated value of a voltage signal of the at least one voltage signal and generating a logic signal according to the calculated value. The detailed calculation of the calculated values will be described below. The current path control unit 36 is coupled to the logic unit 34 and the current path switch 20, for controlling the current path switch 20 according to the logic signal. The current sensing resistor 60 is coupled between the cells 10 and the negative terminal P− of the battery pack 100, and both terminals of the current sensing resistor 60 are coupled to the signal detection unit 32. Further, the negative terminal P− can be a voltage ground.

The group of cells 10 may be composed of a plurality of cells coupled in series. Each cell in the group of cells 10 can be coupled to the signal detection unit 32 respectively, and a corresponding voltage can be measured for each cell, such as VCn, VC1, . . . and so on. The voltage VCn can represent the highest cell voltage of the cells 10, and VSS can represent the voltage ground of the cells 10.

In practical applications, the signal detection unit 32 can be an analog-to-digital converter (ADC), the logic unit 34 can be an arithmetic logic unit (ALU), and the current path control unit 36 can be any circuit that generates a switch signal. The current path switch 20 can include one or more transistors. For example, two NMOS (N-type metal-oxide-semiconductor) transistors can be coupled respectively in the charging path and the discharging path, so as to respectively control charging and the discharging of the battery pack 100. The above-mentioned components are merely examples, and other equivalent circuit components should be within the scope of the present invention.

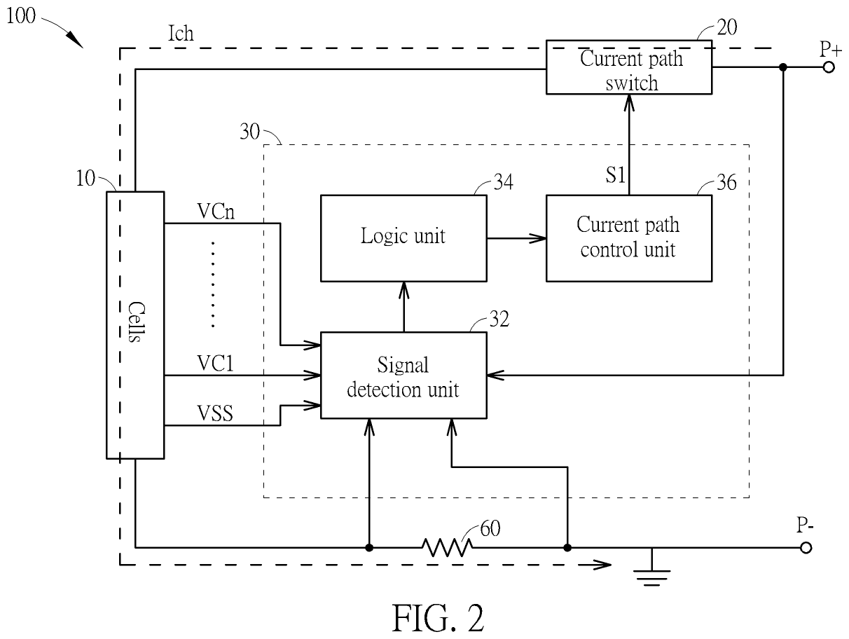

FIG. 2 is a diagram of charging the battery pack 100 in FIG. 1. When the battery pack 100 is being charged, the charging current Ich flows from the positive terminal P+ to the negative terminal P− of the battery pack 100. Normally, the signal detection unit 32 can monitor the voltage across the current sensing resistor 60 to detect whether a short circuit occurs. When a short circuit occurs, the instantaneous current can reach several times of the rated current, which can damage electronic components and cause circuit failure. When abnormality occurs at the current sensing resistor 60, the detected voltage across the current sensing resistor 60 becomes substantially 0V. Thus, current monitoring mechanism fails. To rescue this situation, another current monitoring mechanism is introduced. The current monitoring system 30 can replace the current sensing resistor 60 to monitor the charging current on the current path to detect short circuit current. The current path control unit 36 can send a control signal S1 to control the current path switch 20 according to current detection results. In addition, the signal detection unit 32 can set the voltage signal to be the value of the highest cell voltage VCn with respect to the voltage ground VSS (Vb=VCn−VSS), hereinafter referred to as the voltage Vb.

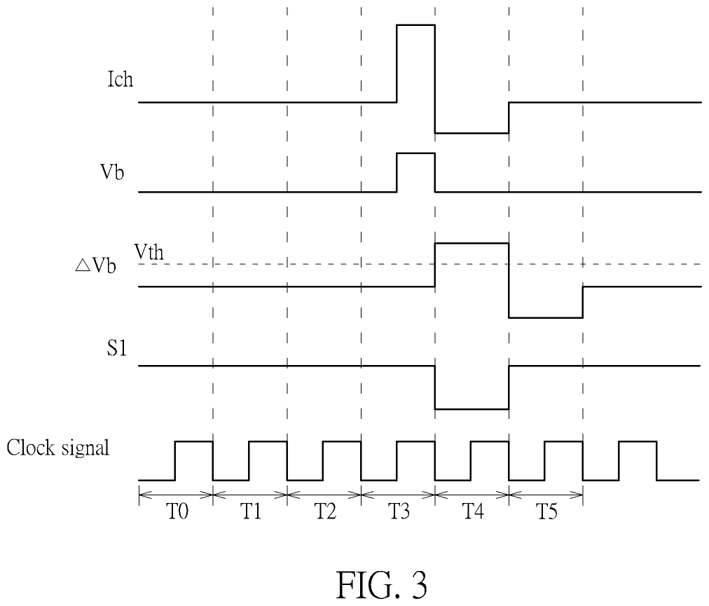

FIG. 3 is a timing diagram of charging the battery pack 100 in FIG. 2. The battery pack 100 is in a normal charging state during periods T0, T1 and T2. Each period is on the order of nanosecond to picosecond. ΔVb in each period is the difference between the average values of voltage Vb in the two preceding periods. Taking period T2 as an example, the charging current Ich is at a normal flow rate, and the voltage Vb is at a normal level. The logic unit 34 calculates the difference ΔVb between the average values of the voltage Vb of the two periods before the period T2 (i.e., ΔVb=Vb_{T1}−Vb_{T0}). ΔVb is the above-mentioned calculated value. In particular, Vb_{T1} represents the average value of the voltage Vb in the period T1, and Vb_{T0} represents the average value of the voltage Vb in the period T0. As such, using average value can avoid glitches affecting the calculation by the logic unit 34. The charging current Ich and the voltage Vb of the two periods proceeding the period T2 (i.e., the period T1 and the period T0) are both in normal state. As such, the difference ΔVb at period T2, which is the average voltage Vb of period T0 subtracted from the average voltage Vb of period T1, is substantially equal to zero. The logic unit 34 then determines that the voltage difference ΔVb is lower than the voltage threshold Vth, and the current path control unit 36 continues to send high-level control signal S1 to maintain the current path switch 20 turned on.

During the period T3, the short-circuit current occurs, and the flow rate of the charging current Ich is pulled up, such that the voltage Vb is also pulled up. The logic unit 34 continuously calculates the difference ΔVb between the average values of the voltage Vb of the two preceding periods. At this time, the voltage difference ΔVb generated by subtracting the average value of the voltage Vb of the period T1 from the average value of the voltage Vb of the period T2 is still substantially equal to zero. The logic unit 34 determines that the voltage difference ΔVb is still lower than the voltage threshold Vth. As such, the current path control unit 36 still sends the high-level control signal S1 to the current path switch 20. Thus, the current path switch 20 maintains turned on.

During the period T4, the logic unit 34 determines that the voltage difference ΔVb generated by subtracting the average value of the voltage Vb of the period T2 from the average value of the voltage Vb of the period T3 (i.e., the voltage difference ΔVb of the two preceding periods) is at a high level greater than the voltage threshold Vth. At this time, the low-level control signal S1 is sent by the current path control unit 36 to turn off the current path switch 20, thus cutting off the charging current Ich. This mechanism prevents the battery pack 100 from being damaged by excessive current, so as to protect the battery pack 100. That is, in the period T4 the current path switch 20 is turned off, and the charging current Ich is substantially equal to 0. Thus, the charging current Ich in the period T4 is lower than that in the periods T0 to T2, and the voltage Vb drops back to the low level.

During period T5, the logic unit 34 determines that the voltage difference ΔVb generated by subtracting the average value of voltage Vb of period T3 from the average value of voltage Vb of period T4 (the voltage difference ΔVb of the two preceding periods) drops to a negative value, which is lower than voltage threshold Vth. At this time, the current path control unit 36 sends out the high-level control signal S1 to turn on the current path switch 20, such that the charging current Ich returns to the normal level. That is, the current path switch 20 is turned on, and the charging current Ich returns to the same level as that of the period T0 to T2. Thus, the voltage Vb is at the normal level. It should be noted that the logic unit 34 continues to calculate the difference ΔVb between the average voltages of the two preceding periods, and the voltage difference ΔVb maintains negative value until the end of the period T5. The operation of the remaining periods is similar, and the description is not repeated herein for brevity.

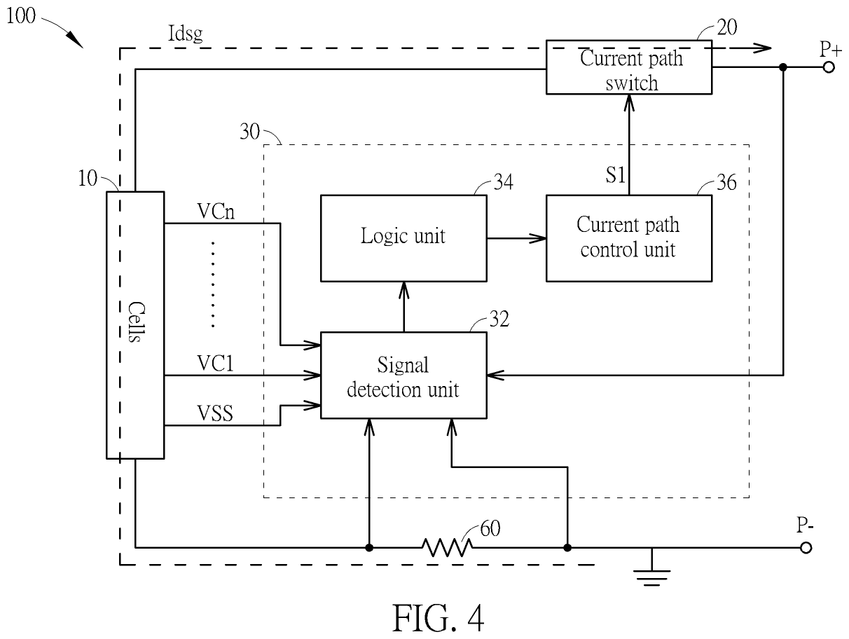

FIG. 4 is a diagram of discharging the battery pack 100 in FIG. 1 of an embodiment. When the battery pack 100 is being discharged, the discharging current Idsg flows from the negative terminal P− to the positive terminal P+ of the battery pack 100. Normally, the signal detection unit 32 can monitor the voltage across the current sensing resistor 60 to detect whether a short circuit occurs. When a short circuit occurs, the instantaneous current can reach several times of the rated current, which can damage electronic components and cause circuit failure. When abnormality occurs at the current sensing resistor 60, the detected voltage across the current sensing resistor 60 becomes substantially 0V. Thus, current monitoring mechanism fails. To rescue this situation, another current monitoring mechanism is introduced. The current monitoring system 30 can replace the current sensing resistor 60 to monitor the discharging current on the current path to detect short circuit current. The current path control unit 36 can send a control signal S1 to control the current path switch 20 according to current detection results. In addition, the signal detection unit 32 can set the voltage signal to be the value of the highest cell voltage VCn with respect to the voltage ground VSS (Vb=VCn−VSS), hereinafter referred to as the voltage Vb.

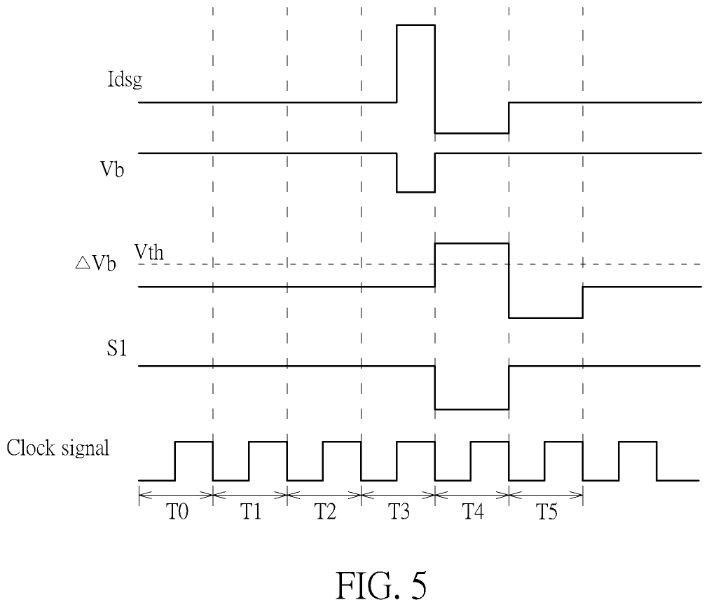

FIG. 5 is a timing diagram of discharging the battery pack 100 in FIG. 4. The battery pack 100 is in a normal discharging state during periods T0, T1 and T2. Each period is on the order of nanosecond to picosecond. ΔVb in each period is the difference between the average values of voltage Vb in the two preceding periods. Taking period T2 as an example, the discharging current Idsg is at a normal flow rate, and the voltage Vb is at a normal level. The logic unit 34 calculates the difference ΔVb between the average values of the voltage Vb of the two periods before the period T2 (i.e., ΔVb=Vb_{T0}−Vb_{T1}). ΔVb is the above-mentioned calculated value. In particular, Vb_{T1} represents the average value of the voltage Vb in the period T1, and Vb_{T0} represents the average value of the voltage Vb in the period T0. As such, using average value can avoid glitches affecting the calculation by the logic unit 34. The discharging current Idsg and the voltage Vb of the two periods proceeding the period T2 (i.e., the period T1 and the period T0) are both in normal state. As such, the difference ΔVb at period T2, which is the average voltage Vb of period T1 subtracted from the average voltage Vb of period T0, is substantially equal to zero. The logic unit 34 then determines that the voltage difference ΔVb is lower than the voltage threshold Vth, and the current path control unit 36 continues to send high-level control signal S1 to maintain the current path switch 20 turned on. It should be noted that the calculation of ΔVb in the embodiment of FIG. 5 is opposite to that in the embodiment of FIG. 3. The ΔVb in the embodiment in FIG. 5 is ΔVb=Vb_{T-2}−Vb_{T-1}. On the contrary, the ΔVb in the embodiment of FIG. 3 is ΔVb=Vb_{T-1}−Vb_{T-2}.

During the period T3, the short-circuit current occurs, and the flow rate of the charging current Idsg is pulled up, such that the voltage Vb is pulled down. The logic unit 34 continuously calculates the difference ΔVb between the average values of the voltage Vb of the two preceding periods. At this time, the voltage difference ΔVb generated by subtracting the average value of the voltage Vb of the period T2 from the average value of the voltage Vb of the period T1 is still substantially equal to zero. The logic unit 34 determines that the voltage difference ΔVb is still lower than the voltage threshold Vth. As such, the current path control unit 36 still sends the high-level control signal S1 to the current path switch 20. Thus, the current path switch 20 maintains turned on.

During the period T4, the logic unit 34 determines that the voltage difference ΔVb generated by subtracting the average value of the voltage Vb of the period T3 from the average value of the voltage Vb of the period T2 (i.e., the voltage difference ΔVb of the two preceding periods) is at a high level greater than the voltage threshold Vth. At this time, the low-level control signal S1 is sent by the current path control unit 36 to turn off the current path switch 20, thus cutting off the charging current Idsg. This mechanism prevents the battery pack 100 from being damaged by excessive current, so as to protect the battery pack 100. That is, in the period T4 the current path switch 20 is turned off, and the discharging current Idsg is substantially equal to 0. Thus, the discharging current Idsg in the period T4 is lower than that in the periods T0 to T2, and the voltage Vb is pulled back to the high level.

During period T5, the logic unit 34 determines that the voltage difference ΔVb generated by subtracting the average value of voltage Vb of period T4 from the average value of voltage Vb of period T3 (the voltage difference ΔVb of the two preceding periods) drops to a negative value, which is lower than voltage threshold Vth. At this time, the current path control unit 36 sends out the high-level control signal S1 to turn on the current path switch 20, such that the discharging current Idsg returns to the normal level. That is, the current path switch 20 is turned on, and the discharging current Idsg returns to the same level as that of the period T0 to T2. Thus, the voltage Vb is at the normal level. It should be noted that the logic unit 34 continues to calculate the difference ΔVb between the average voltages of the two preceding periods, and the voltage difference ΔVb maintains negative value until the end of the period T5. The operation of the remaining periods is similar, and the description is not repeated herein for brevity.

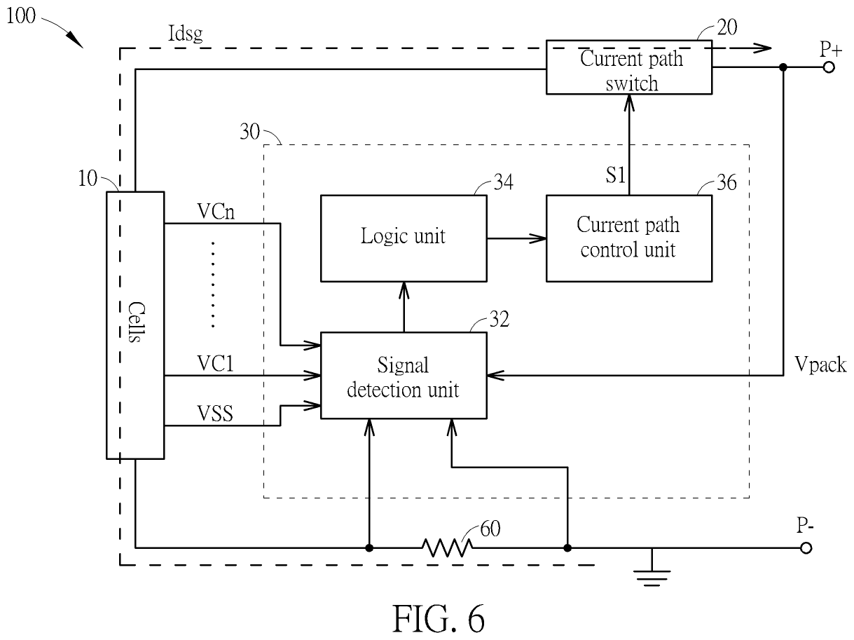

FIG. 6 is a diagram of discharging the battery pack 100 in FIG. 1 of another embodiment. When the battery pack 100 is being discharged, the discharging current Idsg flows from the negative terminal P− to the positive terminal P+ of the battery pack 100. Normally, the signal detection unit 32 can monitor the voltage across the current sensing resistor 60 to detect whether a short circuit occurs. When a short circuit occurs, the instantaneous current can reach several times of the rated current, which can damage electronic components and cause circuit failure. When abnormality occurs at the current sensing resistor 60, the detected voltage across the current sensing resistor 60 becomes substantially 0V. Thus, current monitoring mechanism fails. To rescue this situation, another current monitoring mechanism is introduced. The current monitoring system 30 can replace the current sensing resistor 60 to monitor the discharging current on the current path to detect short circuit current. The current path control unit 36 can send a control signal S1 to control the current path switch 20 according to current detection results. In addition, the signal detection unit 32 can set the voltage signal to be the value of the highest cell voltage VCn with respect to the middle current path (Vb=VCn−Vpack), hereinafter referred to as the voltage Vb. Vpack represents the voltage measured in the middle of the current path in FIG. 6.

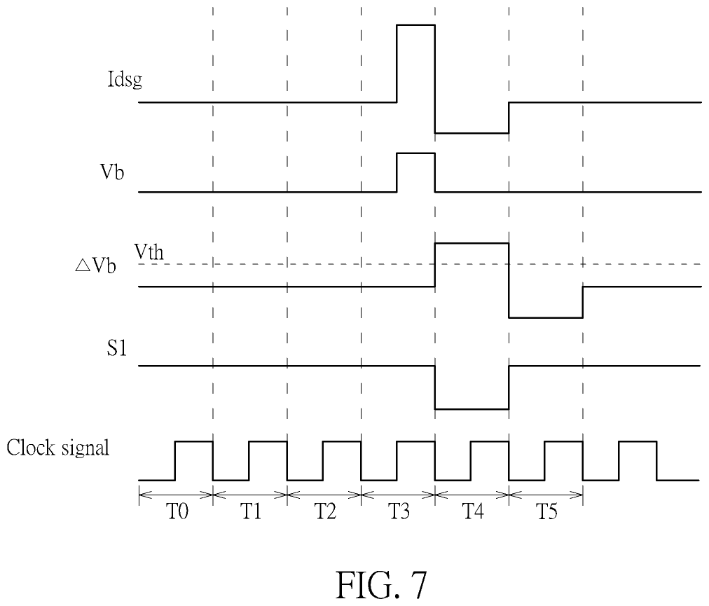

FIG. 7 is a timing diagram of discharging the battery pack 100 in FIG. 6. The battery pack 100 is in a normal discharging state during periods T0, T1 and T2. Each period is on the order of nanosecond to picosecond. ΔVb in each period is the difference between the average values of voltage Vb in the two preceding periods. Taking period T2 as an example, the discharging current Idsg is at a normal flow rate, and the voltage Vb is at a normal level. The logic unit 34 calculates the difference ΔVb between the average values of the voltage Vb of the two periods before the period T2 (i.e., ΔVb=Vb_{T1}−Vb_{T0}). ΔVb is the above-mentioned calculated value. In particular, Vb_{T1} represents the average value of the voltage Vb in the period T1, and Vb_{T0} represents the average value of the voltage Vb in the period T0. As such, using average value can avoid glitches affecting the calculation by the logic unit 34. The discharging current Idsg and the voltage Vb of the two periods proceeding the period T2 (i.e., the period T1 and the period T0) are both in normal state. As such, the difference ΔVb at period T2, which is the average voltage Vb of period T0 subtracted from the average voltage Vb of period T1, is substantially equal to zero. The logic unit 34 then determines that the voltage difference ΔVb is lower than the voltage threshold Vth, and the current path control unit 36 continues to send high-level control signal S1 to maintain the current path switch 20 turned on.

During the period T3, the short-circuit current occurs, and the flow rate of the charging current Idsg is pulled up, such that the voltage Vb is also pulled up. The logic unit 34 continuously calculates the difference ΔVb between the average values of the voltage Vb of the two preceding periods. At this time, the voltage difference ΔVb generated by subtracting the average value of the voltage Vb of the period T1 from the average value of the voltage Vb of the period T2 is still substantially equal to zero. The logic unit 34 determines that the voltage difference ΔVb is still lower than the voltage threshold Vth. As such, the current path control unit 36 still sends the high-level control signal S1 to the current path switch 20. Thus, the current path switch 20 maintains turned on.

During the period T4, the logic unit 34 determines that the voltage difference ΔVb generated by subtracting the average value of the voltage Vb of the period T2 from the average value of the voltage Vb of the period T3 (i.e., the voltage difference ΔVb of the two preceding periods) is at a high level greater than the voltage threshold Vth. At this time, the low-level control signal S1 is sent by the current path control unit 36 to turn off the current path switch 20, thus cutting off the charging current Idsg. This mechanism prevents the battery pack 100 from being damaged by excessive current, so as to protect the battery pack 100. That is, in the period T4 the current path switch 20 is turned off, and the discharging current Idsg is substantially equal to 0. Thus, the discharging current Idsg in the period T4 is lower than that in the periods T0 to T2, and the voltage Vb is pulled back to the low level.

During period T5, the logic unit 34 determines that the voltage difference ΔVb generated by subtracting the average value of voltage Vb of period T3 from the average value of voltage Vb of period T4 (the voltage difference ΔVb of the two preceding periods) drops to a negative value, which is lower than voltage threshold Vth. At this time, the current path control unit 36 sends out the high-level control signal S1 to turn on the current path switch 20, such that the discharging current Idsg returns to the normal level. That is, the current path switch 20 is turned on, and the discharging current Idsg returns to the same level as that of the period T0 to T2. Thus, the voltage Vb is at the normal level. It should be noted that the logic unit 34 continues to calculate the difference ΔVb between the average voltages of the two preceding periods, and the voltage difference ΔVb maintains negative value during the period T5. The operation of the remaining periods is similar, and the description is not repeated herein for brevity.

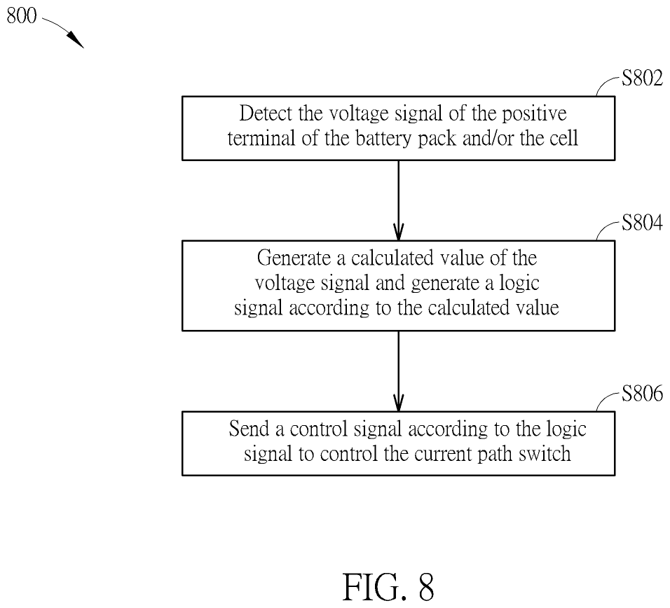

FIG. 8 is a flowchart of the current monitoring method 800 of the battery pack 100 in FIG. 1. The current monitoring method 800 includes the following steps:
S802: Detect the voltage signal of the positive terminal of the battery pack 100 and/or the cell 10 by the signal detection unit 32;
S804: Generate a calculated value of the voltage signal and generate a logic signal according to the calculated value by the logic unit 34; and
S806: Send a control signal S1 by the current path control unit 36 according to the logic signal to control the current path switch 20.

The details of the current monitoring method 800 have already been described in the above paragraphs. It is not repeated herein for brevity.

In summary, the battery pack and its current monitoring method according to the various embodiments of the present invention implement the current monitoring system to monitor charging and discharging current on the current path when the current sensing resistor becomes abnormal. Therefore, it is an alternative mechanism for detecting whether short circuit current occurs. Moreover, the current path control unit can send control signals according to current detection results to control the current path switch, so as to protect the battery pack by preventing the battery pack from being damaged by excessive current.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A battery pack comprising:
a group of cells;
a current path switch coupled to the group of cells; and
a current monitoring system comprising:
a signal detection unit coupled to the group of cells and/or a positive terminal of the battery pack, configured to detect at least one voltage signal of the group of cells and/or of the positive terminal of the battery pack;
a logic unit coupled to the signal detection unit, configured to generate a calculated value of a voltage signal of the at least one voltage signal and generate a logic signal according to the calculated value; and
a current path control unit coupled to the logic unit and the current path switch, configured to control the current path switch according to the logic signal.

2. The battery pack of claim 1 further comprising a current sensing resistor coupled between the group of cells and a negative terminal of the battery pack, and two terminals of the current sensing resistor are coupled to the signal detection unit.

3. The battery pack of claim 1, wherein the calculated value is a difference of an average value of the voltage signal of the at least one voltage signal within a first time period and an average value of the voltage signal of the at least one voltage signal within a second time period.

4. The battery pack of claim 3, wherein when the logic unit determines the difference to be higher than a threshold, the current path control unit turns off the current path switch.

5. The battery pack of claim 3, wherein when the logic unit determines the difference to be lower than a threshold, the current path control unit turns on the current path switch.

6. The battery pack of claim 1, wherein the voltage signal is a highest voltage of the group of cells.

7. The battery pack of claim 1, wherein the voltage signal is a voltage measured at the positive terminal of the battery pack.

8. The battery pack of claim 1, wherein the voltage signal is a voltage across a terminal with a highest voltage of the group of cells and the positive terminal of the battery pack.

9. The battery pack of claim 1, wherein the group of cells comprises a plurality of cells coupled in series.

10. The battery pack of claim 1, wherein each cell in the group of cells is coupled respectively to the signal detection unit.

11. A current monitoring method for a battery pack, the battery pack comprising a group of cells, a current path switch and a current monitoring system, the current monitoring system comprises a signal detection unit, a logic unit and a current path control unit, the current path switch being coupled to the group of cells, the signal detection unit being coupled to the group of cells and/or a positive terminal of the battery pack, the logic unit being coupled to the signal detection unit, and the current path control unit being coupled to the logic unit and the current path switch, and the method comprising:
detecting at least one voltage signal of the group of cells and/or of the positive terminal of the battery pack by the signal detection unit;
generating a calculated value of a voltage signal of the at least one voltage signal;
generating a logic signal according to the calculated value by the logic unit; and
controlling the current path switch according to the logic signal by the current path control unit.

12. The method of claim 11, wherein the calculated value is a difference of an average value of the voltage signal of the at least one voltage signal within a first time period and an average value of the voltage signal of the at least one voltage signal within a second time period.

13. The method of claim 11, wherein when the logic unit determines the difference to be higher than a threshold, the current path control unit turns off the current path switch.

14. The method claim 11, wherein when the logic unit determines the difference to be lower than a threshold, the current path control unit turns on the current path switch.

15. The method of claim 11, wherein the voltage signal is a highest voltage of the group of cells.

16. The method of claim 11, wherein the voltage signal is a voltage measured at the positive terminal of the battery pack.

17. The method of claim 11, wherein the voltage signal is a voltage across a terminal with a highest voltage of the group of cells and the positive terminal of the battery pack.
